(19) United States
(12) Patent Application Publication
(10) Pub. No.: US 2008/0181007 A1
(43) Pub. Date: Jul. 31, 2008

(54) Semiconductor Device with Reduced Structural Pitch and Method of Making the Same

(75) Inventors: Roman Knoefler, Dresden (DE); Christoph Ludwig, Langebruck (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/668,249

(22) Filed: Jan. 29, 2007

(51) Int. Cl. B32B 3/00; B05D 1/32; G11C 16/06

(52) U.S. Cl. 365/185.17; 427/272; 428/156

(57) ABSTRACT

A method of manufacturing structures in a workpiece includes: providing a portion of a cover layer on a predetermined section of the workpiece, providing a resist layer over the workpiece and the cover layer, and patterning resist structures in the resist layer. The workpiece is patterned using the patterned resist layer and the cover layer as an etching mask. Another method of manufacturing structures in a workpiece includes: providing a resist layer over the workpiece, and patterning resist structures in the resist layer. The workpiece is patterned using the patterned resist layer as an etching mask, thereby obtaining workpiece structures. The workpiece structures are removed from a predetermined section of the workpiece. Thereafter, a pitch fragmentation process is carried out.

### BACKGROUND

Devices comprising structures having dimensions in the range below one micrometer are in wide-spread use today. Not only semiconductor devices, like for instance microprocessors and memory devices, but also micromechanical systems, like sensors and actors, comprise such structures. For manufacturing such structures often methods known from manufacturing semiconductor devices, (e.g., lithography, deposition and etching), are used.

While manufacturing such devices, structures having different dimensions require alignment, e.g., in the same level. The alignment of structures to small structures is very complicated and causes defects, rework and/or yield losses.

### SUMMARY

A method of manufacturing structures in a workpiece may comprise: providing a portion of a cover layer on a predetermined section of the workpiece, providing a resist layer over the workpiece and the cover layer, and patterning resist structures in the resist layer. The workpiece may be patterned using the patterned resist layer and the cover layer as an etching mask.

A method of manufacturing structures in a workpiece may comprise: providing a resist layer over the workpiece and patterning resist structures in the resist layer. The workpiece may be patterned using the patterned resist layer as an etching mask, thereby obtaining workpiece structures. The workpiece structures may be removed from a predetermined section of the workpiece. Thereafter, a pitch fragmentation process may be carried out.

The above and still further features and advantages of the described devices and methods will become apparent upon consideration of the following definitions, descriptions and descriptive figures of specific embodiments thereof, wherein like reference numerals in the various figures are utilized to designate like components. While these descriptions go into specific details of the devices and methods, it should be understood that variations may and do exist and would be apparent to those skilled in the art based on the descriptions herein.

### BRIEF DESCRIPTION OF THE DRAWINGS

The accompanying drawings are included to provide a further understanding of the described devices and methods and are incorporated in and constitute a part of this specification. Other embodiments of the present invention and many of the intended advantages of the described devices and methods will be readily appreciated as they become better understood by reference to the following detailed description. The elements of the drawings are not necessarily to scale relative to each other. The described methods and devices are explained in more detail below with reference to exemplary embodiments, where:

FIGS. 1A to 1D illustrate flow diagrams of embodiments of the described method;

FIGS. 2A to 2H illustrate a schematic cross section through an exemplary embodiment of a workpiece for different processing steps of an embodiment of the method of FIG. 1A;

FIG. 2I illustrates a plan view on an embodiment of a workpiece;

FIGS. 3A to 3G illustrate a schematic cross section through an exemplary embodiment of a workpiece for different processing steps of the method of FIG. 1B;

FIG. 4A illustrates a plan view on an embodiment of the described memory device;

FIG. 4B illustrates a schematic cross section through the memory device of FIG. 4A;

FIG. 4C illustrates a detail of the memory device of FIG. 4A;

FIG. 5A illustrates a plan view on an embodiment of the described memory device;

FIG. 5B illustrates a schematic cross section through the memory device of FIG. 5A;

FIG. 5C illustrates another schematic cross section through the memory device of FIG. 5A;

FIG. 5D illustrates a detail of the memory device of FIG. 5A;

FIGS. 6A and 6B illustrate plan views on embodiments of the described device;

FIG. 7 illustrates a plan view on an embodiment of the described device; and

FIG. 8 illustrates a system comprising a described device.

### DETAILED DESCRIPTION

In the following detailed description, reference is made to the accompanying drawings, which form a part hereof, and in which is shown by way of illustration specific embodiments by which the invention may be practiced. In this regard directional terminology, such as “top”, “bottom”, “front”, “back”, “leading”, “trailing”, etc. is used with reference to the orientation of the Figures being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the described methods and devices is defined by the claims.

As used herein and in the claims, the term pitch refers to a substantially uniform, regular, or periodic interval between adjacent structures arranged in a series or the like, where the pitch is measured from a first side of a first structure to the first side of a second adjacent structure (i.e., the pitch equals the spacing between the structures plus the dimension (e.g., width) of one of the structures). In the following paragraphs exemplary embodiments of the devices and/or the methods are described in connection with figures.

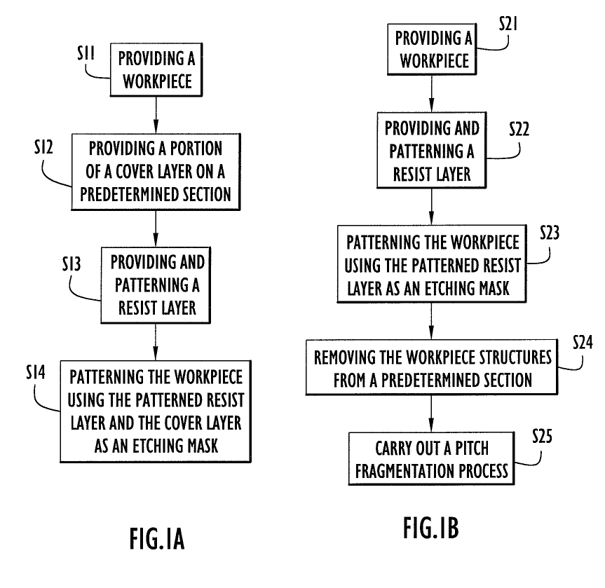

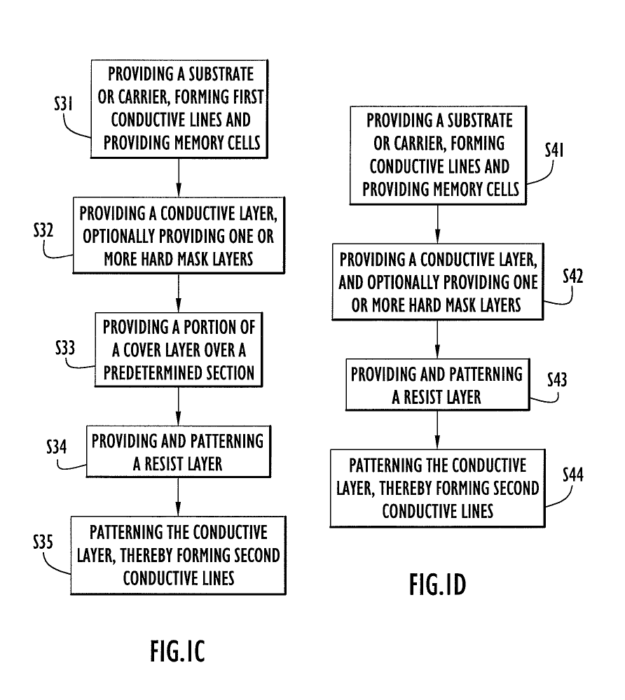

FIG. 1A shows a flow diagram of an embodiment of the described method. First, a workpiece is provided (S11). The workpiece may comprise any type of substrate or carrier (e.g., a semiconductor substrate, an insulating or a conducting substrate or others). The workpiece may comprise a structure layer to be patterned. The structure layer may for instance comprise a conductive layer and optional one or more hard mask layers or may comprise any other layer (e.g., an insulating or semiconducting layer). Nevertheless, the workpiece itself may be patterned. The workpiece may for instance comprise memory cells and first conductive lines. Furthermore, it may comprise layers of different materials, (e.g., semiconductor material, metals, insulating materials, organic materials or others).

A portion of a cover layer is provided on a predetermined section of the workpiece (S12). The cover layer may be a hard mask. The workpiece can be selectively patterned with respect to the cover layer. In other words, the cover layer has a lower etch rate than the workpiece or the structure layer of the workpiece for an etching process used to pattern the workpiece or the structure layer.

A resist layer is provided over the workpiece and the cover layer and subsequently patterned (S13). Thereby, resist structures are obtained in the resist layer. The resist layer may be, for example, a photoresist, which can be patterned by a photolithographic process.

The workpiece may be patterned using the patterned resist layer and the cover layer as an etching mask (S14). Thereby, the resist structures are transferred into the workpiece or the structure layer of the workpiece except in the predetermined section covered by the cover layer.

Thus, for example, large structures in the predetermined section of the workpiece and small structures outside the predetermined section may be obtained in the structure layer of the workpiece in one patterning step while small structures are patterned in the resist layer all over the workpiece. A uniform patterning of small structures in the resist layer is advantageous for instance for photolithographic processes. The large structures may be used for alignment of structures which are subsequently formed in the workpiece. For example, at least a part of the large structure may be removed by a subsequent process; the process comprising an alignment of the part to be removed to the large structure. Alignment of subsequent structures to large structures is simplified and shows better results than alignment to small structures.

In a further embodiment, a pitch fragmentation process may be carried out optionally after patterning the workpiece. Thus smaller structures or structures with a smaller pitch may be obtained in the workpiece while using a standard resist patterning process resulting in larger resist structures or in resist structures with a greater pitch than the size and the pitch of the workpiece structures, respectively. By way of example, structures with a smaller size than the size obtainable by a specific lithography process may be obtained, in other words, these structures may have a sub-lithographic size.

FIG. 1B shows a flow diagram of a further embodiment of the described method. At first a workpiece is provided (S21). The workpiece comprises a structure layer to be structured. The workpiece may comprise different layers, devices and materials as described with respect to FIG. 1A.

A resist layer is provided over the workpiece and the cover layer and patterned (S22). Thereby, resist structures are obtained in the resist layer. The resist structures are larger or have a larger pitch than workpiece structures which are eventually to be manufactured. Thus, alignment of subsequently patterned structures to the resist structures is easy.

The workpiece is patterned using the patterned resist layer as an etching mask (S23). Thereby, the resist structures are transferred into the workpiece or the structure layer of the workpiece such that workpiece structures are obtained.

The workpiece structures are removed from a predetermined section of the workpiece (S24). Since the workpiece structures at this processing step have dimensions relative to the dimensions of the resist structures obtained in step S22, the alignment of the predetermined section of the workpiece to the workpiece structures is relaxed.

Thereafter, a pitch fragmentation process is carried out (S25). Thereby additional workpiece structures are formed between the previously obtained workpiece structures. The resulting workpiece structures outside the predetermined section are smaller or have a smaller pitch than the workpiece structures obtained in step S23. A large structure is obtained within the predetermined section. This large structure may be used for alignment of subsequent structures as described with respect to FIG. 1A.

Both embodiments of the described method have in common that small workpiece structures are patterned only outside a predetermined section of the workpiece after defining a large structure within the predetermined section.

FIG. 1C shows a flow diagram of an embodiment of the described method. First, a substrate or carrier is provided, first conductive lines are formed and memory cells are provided (S31). Alternatively, first conductive lines and memory cells may also be formed in a later process step. The substrate may comprise any type of substrate (e.g., a semiconductor substrate, an insulating or a conducting substrate or others). The substrate may further comprise layers of different materials (e.g., semiconductor material, metals, insulating materials, organic materials or others, or other devices).

A conductive layer for forming second conductive lines is provided. Optional one or more hard mask layers may be provided on the conductive layer (S32).

A portion of a cover layer is provided over a predetermined section of the conductive layer (S33). The cover layer may for instance be a hard mask. The conductive layer can be selectively patterned with respect to the cover layer. In other words, the cover layer has a lower etch rate than the conductive layer or the hard mask layers on the conductive layer for an etching process used to pattern the conductive layer or the hard mask layer.

A resist layer is provided over the conductive layer and the cover layer and patterned (S34). Thereby, resist structures are obtained in the resist layer. The resist layer may for example be a photoresist, which can be patterned by a photolithographic process.

Second conductive lines are formed by patterning the conductive layer (S35). Forming the second conductive lines comprises an etching step using the patterned resist layer and the cover layer as an etching mask. As a result, at least a part of the memory cells is connected to at least one of the first conductive lines and of the second conductive lines.

In a further embodiment, a pitch fragmentation process can be carried out optionally after patterning the conductive layer or after patterning the hard mask layer on the conductive layer. Thus, smaller structures or structures with a smaller pitch may be obtained in the conductive layer while using a standard resist patterning process for obtaining larger resist structures or resist structures with a greater pitch.

FIG. 1D shows a flow diagram of a further embodiment of the described method. First, a substrate or carrier is provided, first conductive lines are formed and memory cells are provided (S41). Nevertheless, first conductive lines and memory cells may also be formed in a later process step. The substrate may further comprise different layers, devices and materials as described with respect to FIG. 1C.

A conductive layer for forming second conductive lines is provided. Optional one or more hard mask layers may be provided on the conductive layer (S42).

A resist layer is provided over the conductive layer and patterned (S43). Thereby, resist structures are obtained in the resist layer. The resist structures are larger or have a larger pitch than second conductive lines which are eventually to be manufactured. Thus, alignment of subsequently patterned structures to the resist structures is easy.

Second conductive lines are formed by patterning the conductive layer (S44). Forming the second conductive lines comprises: an etching step using the patterned resist layer as an etching mask, removing structures obtained by the etching step from a predetermined section of the conductive layer, and carrying out a pitch fragmentation process after removing the structures. As a result, at least a part of the memory cells is connected with at least one of the first conductive lines and of the second conductive lines.

The memory device manufactured by the method described with respect to FIGS. 1C and 1D may, for example, be a semiconductor memory device, and the memory cells may, for instance, be formed at least partially within a semiconductor substrate.

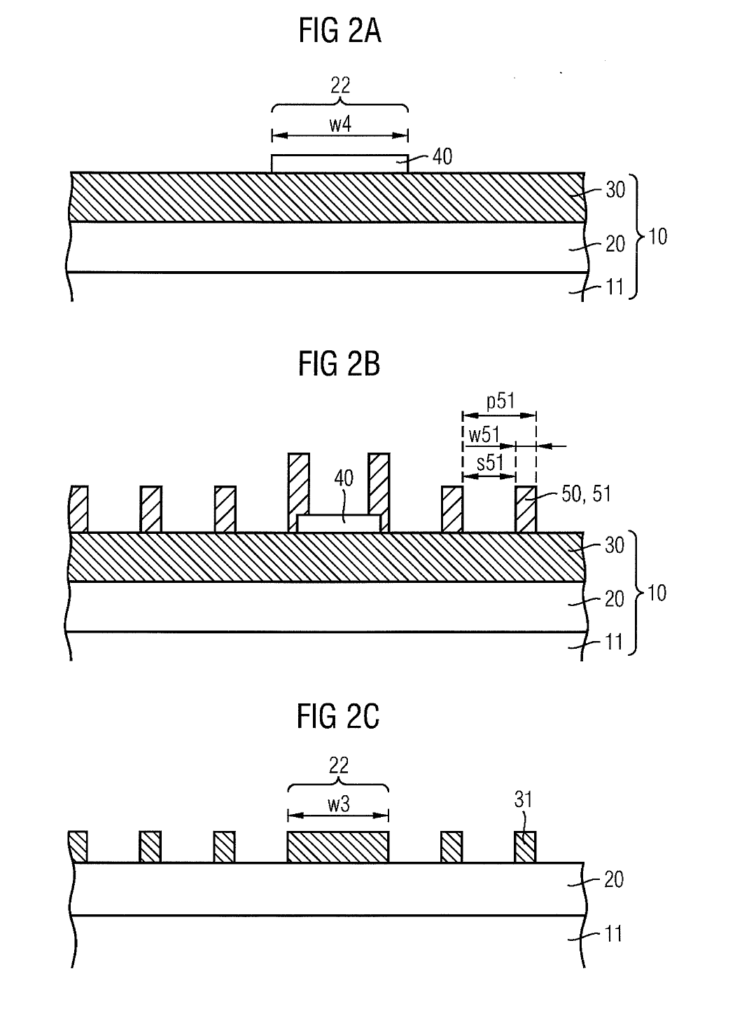

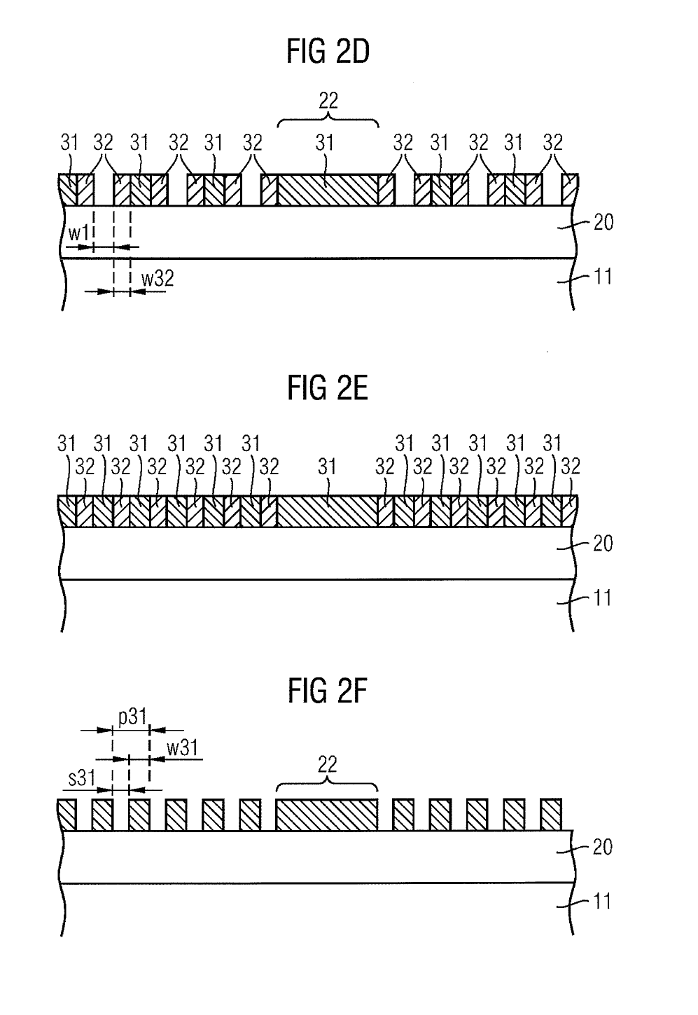

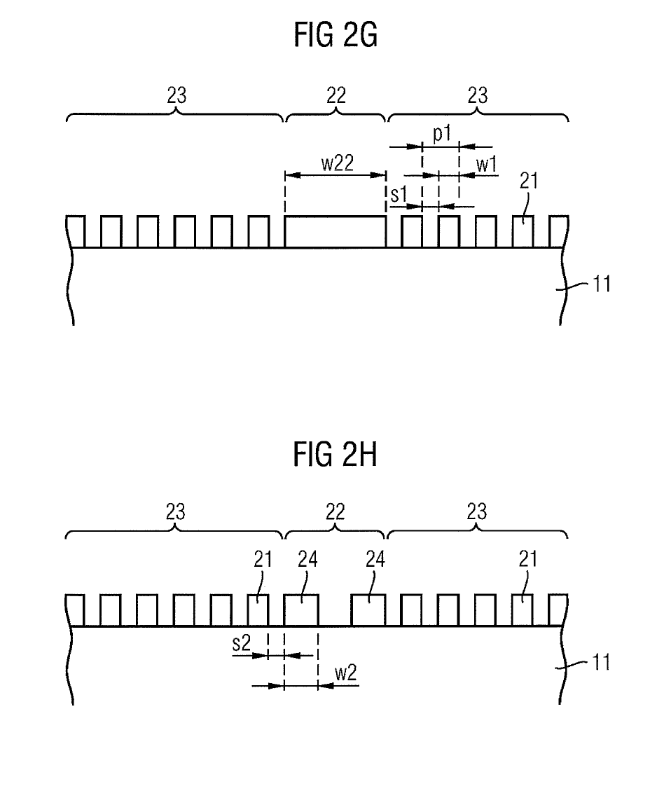

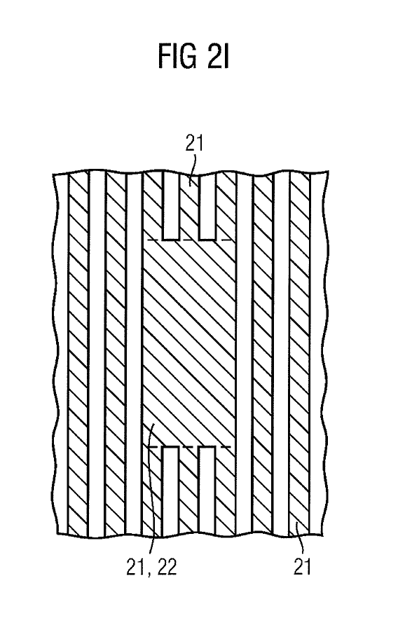

FIGS. 2A to 2H illustrate cross sections through an embodiment of a workpiece after different processing steps of an embodiment of the method of FIG. 1A.

FIG. 2A shows a workpiece 10 comprising by way of example a substrate 11, a structure layer 20 and a masking layer 30. Substrate 11 may for instance comprise a semiconductor material (e.g., silicon, which may comprise memory cells, active regions, conductive lines, buried layers, insulating regions, and others). Structure layer 20 may for instance be formed of a semiconducting material or a metallic material. Masking layer 30 may for example comprise a hard mask of any suitable material (e.g., an insulating material or an organic material). A portion of a cover layer 40 is provided on a predetermined section 22 of workpiece 10. The portion of cover layer 40 may for instance be formed in the shape of a line or in a rectangular shape and may have a width w4.

A resist layer 50 is provided over workpiece 10 and cover layer 40 and patterned. Thereby resist structures 51 are obtained. The resulting structure is shown in FIG. 2B. As can be seen in FIG. 2B, resist structures 51 may have a small width w51 and a large pitch p51, wherein p51=w51+s51. S51 is the distance between two neighboring resist structures 51. Nevertheless, it is possible to pattern resist structures 51 having any other width w51 and pitch p51 (e.g., a small width w51 and a small pitch p51). Resist structures 51 are formed over the whole surface of workpiece 10, in other words in predetermined section 22 and outside predetermined section 22. Resist structures 51 may be aligned with respect to cover layer 40 such that one edge of a first resist structure 51 overlaps one edge, i.e., a first edge, of cover layer 40 and one edge of another, i.e., a second, resist structure 51 overlaps another, i.e., a second, edge of cover layer 40.

Resist structures 51 are transferred into masking layer 30 outside section 22 of workpiece 10, in other words, into that sections of masking layer 30 not covered by cover layer 40. Thereby masking structures 31 are obtained, as can be seen in FIG. 2C. Masking structures 31 outside section 22 have dimensions that are related to the dimensions of resist structures 51, whereas masking structure 31 in section 22 has a width w3 related to w4 and w51. The relation of the dimensions of masking structures 31 to the dimensions of first and second resist structures 51 and of cover layer portion 40 may depend on the process used to transfer resist structures 51 into masking layer 30. For example, the dimensions of masking structures 31 outside section 22 may be equal to the dimensions of resist structures 51. The width of masking structure inside section 22 (w3) may for instance equal the sum of 2×w51+s51, and w3 may equal w4 or may be larger than w4.

A pitch fragmentation process may be carried out in order to obtain masking structures 31 having a smaller pitch or a smaller width and pitch than masking structures obtained by transferring resist structures 51 into masking layer 30. An embodiment of the pitch fragmentation process will be described with respect to FIGS. 2D to 2F. Nevertheless other embodiments of the pitch fragmentation process are possible. Furthermore, the described method may be carried out without carrying out a pitch fragmentation process in the case that resist structures 51 may be obtained which have such dimensions that workpiece structures may be patterned having desired dimensions.

A pitch fragmentation process causes a reduction of the pitch of respective structures. The pitch fragmentation process comprises: forming spacers at the sidewalls of present structures, forming an additional material in spaces between the spacers, and removing the spacers after forming the additional material. Thus additional structures are formed in between the already present structures, thereby reducing the pitch and possibly also the size of the structures. For instance, the pitch fragmentation process may comprise an etching process before forming spacers resulting in smaller structure sizes. Accordingly, it is, for example, possible to obtain structures having a size smaller than the structural feature size F which may be obtained by the technology used.

As can be seen in FIG. 2D, spacers 32 are formed at the sidewalls of masking structures 31. Spacers 32 may be formed without changing the width of masking structures 31, for instance by conformally depositing a spacer material followed by an anisotropic etching process, as can be seen in FIG. 2D. Nevertheless, spacers 32 may be formed consuming a part of the material of masking structures 31, for instance by forming a compound of the material of masking structures 31 and of an additional material. This may be achieved for instance by oxidizing a silicon material of masking structures 31. The width w32 of spacers 32 may be adjusted such that the space between two adjacent spacers 32 has a width w1 which equals the width of workpiece structures to be patterned. The material of spacers 32 may be freely chosen, as long as the material of spacers 32 can selectively be removed with respect to the material of masking structures 31.

Thereafter a material is deposited into the spaces between spacers 32. As can be seen in FIG. 2E, the deposited material may be the same material as of masking layer 30, therefore masking structures 31 are deposited between spacers 32. As can be seen, spacers 32 and masking structures 31 are arranged alternating. Nevertheless, the deposited material may be of any other material, as long as the material of spacers 32 can selectively be removed with respect to the deposited material.

After depositing a material into the spaces between spacers 32, spacers 32 are removed, by way of example by an etching process. The resulting structure is shown in FIG. 2F. As can be seen, masking structures 31 outside section 22 have a width w31 and a pitch p31, wherein p31=w31+s31. S31 is the space between two neighboring masking structures 31. In the embodiment shown in FIG. 2F, w31 is equal for all masking structures outside section 22.

As a result of the pitch fragmentation process described with respect to FIGS. 2D to 2F, the pitch of masking structures 31 is reduced with respect to the pitch of masking structures 31 obtained by transferring resist structures 51 into masking layer 30.

After obtaining masking structures 31 having desired dimensions for patterning workpiece structures, masking structures 31 are transferred into structure layer 20. The resulting structure is shown in FIG. 2G. Obtained workpiece structures 21 outside section 22 may be uniformly formed and arranged in subsets 23. Each workpiece structure 21 in subset 23 has a width w1, a distance s1 to a neighboring workpiece structure 21, and a pitch p1=w1+s1. Workpiece structure 21 within section 22 has a width w22 which is greater than p1, wherein w1 and w22 are related to w31 and w3, respectively.

As is shown in FIG. 2G, a device comprises a plurality of first structures 21 having a pitch p1 and a dimension d1. Dimension d1 may be width w1 or may be distance s1. In an embodiment of the described device, p1 is smaller than 100 nm, for instance smaller than 80 nm, and d1 is smaller than 50 nm, for instance smaller than 40 nm. The first structures are arranged in subsets 23 and may be formed uniformly. The device further comprises a structure section 22 which is arranged between different subsets 23 and has a width w22 greater than workpiece structure pitch p1.

Workpiece structure 21 in section 22 may be further patterned. By way of example, a part of workpiece structure 21 in section 22 may be removed thereby obtaining additional workpiece structures 24, as can be seen in FIG. 2H. Additional structures 24 have a width w2, which may be greater than w1, and are arranged at the edges of subsets 23 having a distance s2 to a first structure 21 of a respective subset 23. In one embodiment s2 equals s1.

For example, workpiece structures 21 may be conductive lines running along a first direction and additional structures 24 may be additional conductive lines also running along the first direction. W2 may for instance be greater than 2×w1. For example, structures 21 may be wordlines of a NAND string, and structures 24 may be select gate lines, wherein the distance s2 between wordlines and select gate lines is smaller than 100 nm. S2 may, for instance, equal dimension d1 as described with respect to FIG. 2G.

Nevertheless, any other workpiece structures 21 may be manufactured by the described methods, for example, structures in a metallic layer, (e.g., landing pad structures and fan-out structures, or active area structures in a semiconductor substrate or micromechanical structures in any workpiece). It is also possible to manufacture landing pads in a wiring level by merging conductive lines. In other words, structure 21 in section 22 may be a landing pad connected with conductive lines which may be structures 21 outside section 22. FIG. 2I shows a plan view on such a workpiece.

Furthermore, further patterning of section 22 may be carried out subsequent to the process resulting in the structure shown in FIG. 2F. In other words, at least a part of masking structure 31 in section 22 of FIG. 2F may be removed before transferring masking structures 31 into structure layer 20. Thereby, a subsequent transferring of the masking structures 31 into the structured layer 20 would result in forming, for example, the structure as shown in FIG. 2H.

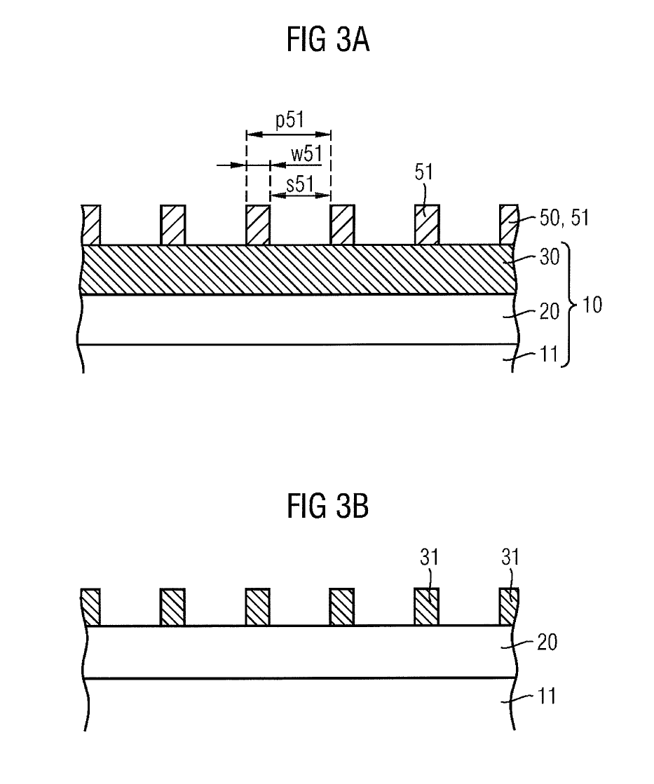

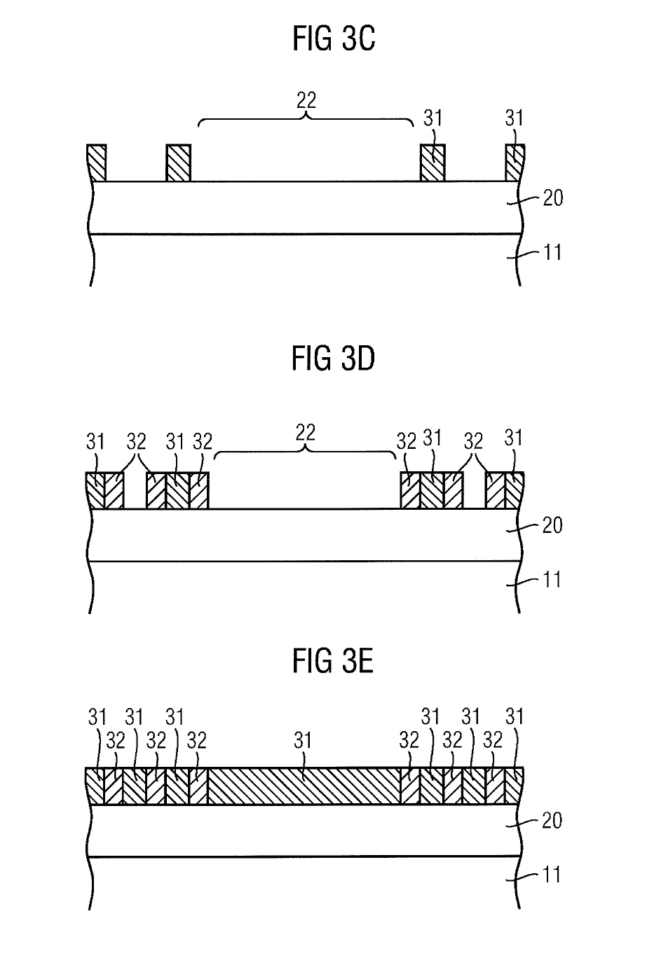

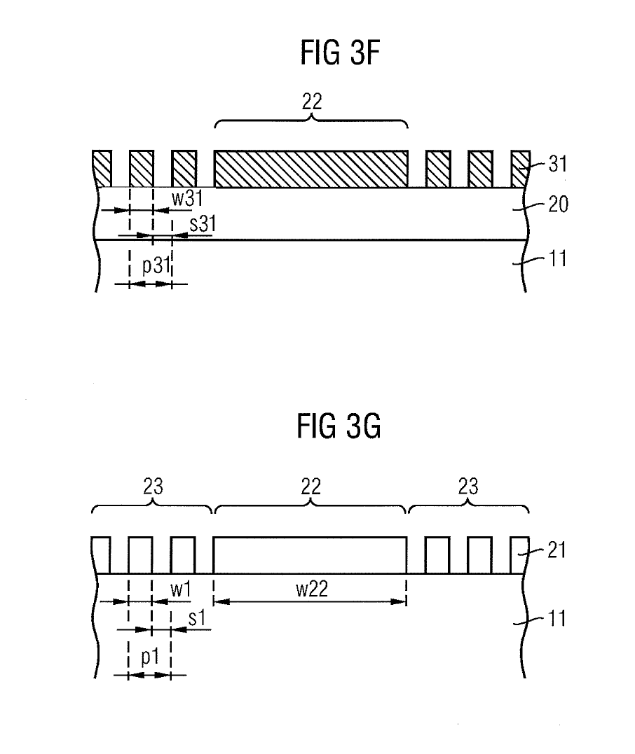

FIGS. 3A to 3G illustrate cross sections through an embodiment of a workpiece for different processing steps of an embodiment of the method of FIG. 1B.

FIG. 3A shows a workpiece 10 comprising for example a substrate 11, a structure layer 20 and a masking layer 30, as described with respect to FIG. 2A. A resist layer 50 is provided over workpiece 10 and patterned. Thereby resist structures 51 are obtained. As can be seen in FIG. 3A, resist structures 51 may have a small width w51 and a large pitch p51, wherein p51=w51+s51. S51 is the distance between two neighboring resist structures 51. Nevertheless, resist structures 51 may be equal line/space structures, that is w51 equals s51. Resist structures 51 are formed over the whole surface of workpiece 10.

Resist structures 51 are transferred into masking layer 30 over the whole surface of workpiece 10. Thereby, masking structures 31 are obtained, as can be seen in FIG. 3B. Masking structures 31 have dimensions related to the dimensions of resist structures 51. It is possible to obtain masking structures 31 having smaller sizes than resist structures 51 by using a suitable transfer process.

Thereafter, masking structures 31 are removed from a predetermined section 22 of workpiece 10, for instance by an etching process. The resulting structure is shown in FIG. 3C.

A pitch fragmentation process is carried out in order to obtain masking structures 31 having a smaller pitch or a smaller width and pitch than masking structures obtained by transferring resist structures 51 into masking layer 30. An embodiment of the pitch fragmentation process will be described with respect to FIGS. 3D to 3F. Nevertheless other embodiments of the pitch fragmentation process are possible, as described with respect to FIGS. 2D to 2F.

As can be seen in FIG. 3D, spacers 32 are formed at the sidewalls of masking structures 31, as described with respect to FIG. 2D. Spacers 32 may be formed without changing the width of masking structures 31, as can be seen in FIG. 3D. Nevertheless, it is possible to reduce the width of masking structures 31 before forming spacers 32 or while forming spacers 32.

Thereafter, a material is deposited into the spaces between spacers 32, including in the space of the predetermined section 22. As can be seen in FIG. 3E, the deposited material may be the same material as of masking layer 30, therefore masking structures 31 are deposited between spacers 32. As can be seen in FIG. 3E, spacers 32 and masking structures 31 are arranged alternating.

After depositing a material into the spaces between spacers 32, spacers 32 are removed, for example by an etching process. The resulting structure is shown in FIG. 3F. As can be seen, masking structures 31 outside section 22 have a width w31 and a pitch p31, wherein p31=w31+s31. S31 is the space between two neighboring masking structures 31. In the embodiment shown in FIG. 3F, w31 is equal for all masking structures outside section 22.

As a result of the pitch fragmentation process described with respect to FIGS. 3D to 3F, the pitch of masking structures 31 is reduced with respect to the pitch of masking structures 31 obtained by transferring resist structures 51 into masking layer 30.

After obtaining masking structures 31 having desired dimensions for patterning workpiece structures, masking structures 31 are transferred into structure layer 20. The resulting structure is shown in FIG. 3G. Obtained workpiece structures 21 outside section 22 may be uniformly formed and arranged in subsets 23. Each workpiece structure 21 in subset 23 has a width w1, a distance s1 to a neighboring structure 21, and a pitch p1=w1+s1. Workpiece structure 21 within section 22 has a width w22 which is greater than p1.

Workpiece structure 21 in section 22 can be further patterned as described with respect to FIG. 2H. Nevertheless, it is possible to pattern masking structure 31 in section 22 shown in FIG. 3F before transferring masking structures into structure layer 20.

A memory device comprises a plurality of first conductive lines, a plurality of second conductive lines, a plurality of additional conductive lines, and a plurality of memory cells. The first conductive lines run along a first direction. The second conductive lines run along a second direction and are arranged in subsets. The second conductive lines have a width w1 smaller than 50 nm and a pitch p1 smaller than 100 nm. The additional conductive lines run along the second direction. Each additional conductive line is arranged at an edge of a respective subset of second conductive lines and has a width w2 greater than w1. At least a part of the memory cells is configured to be addressed by one or more of the first conductive lines and of the second conductive lines.

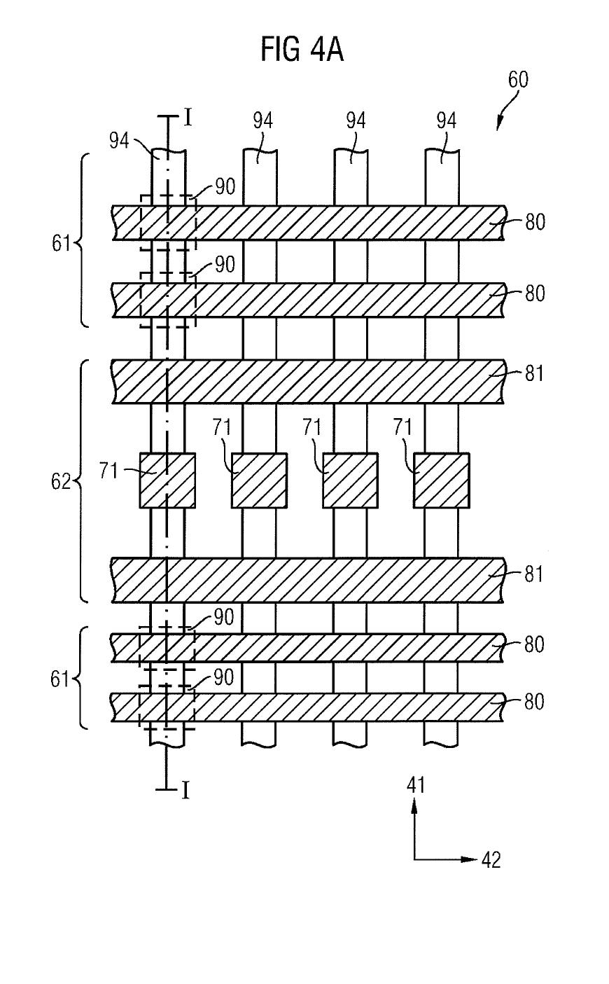

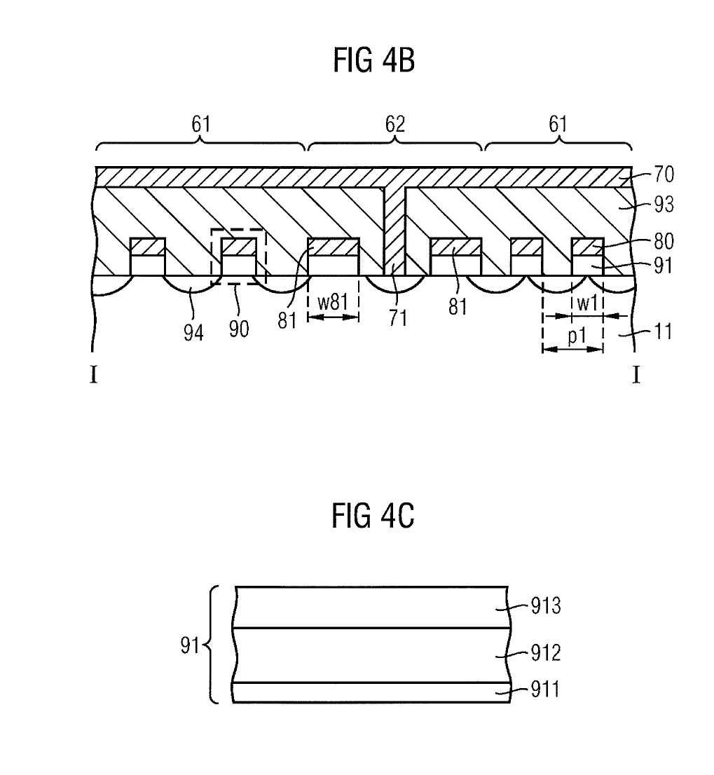

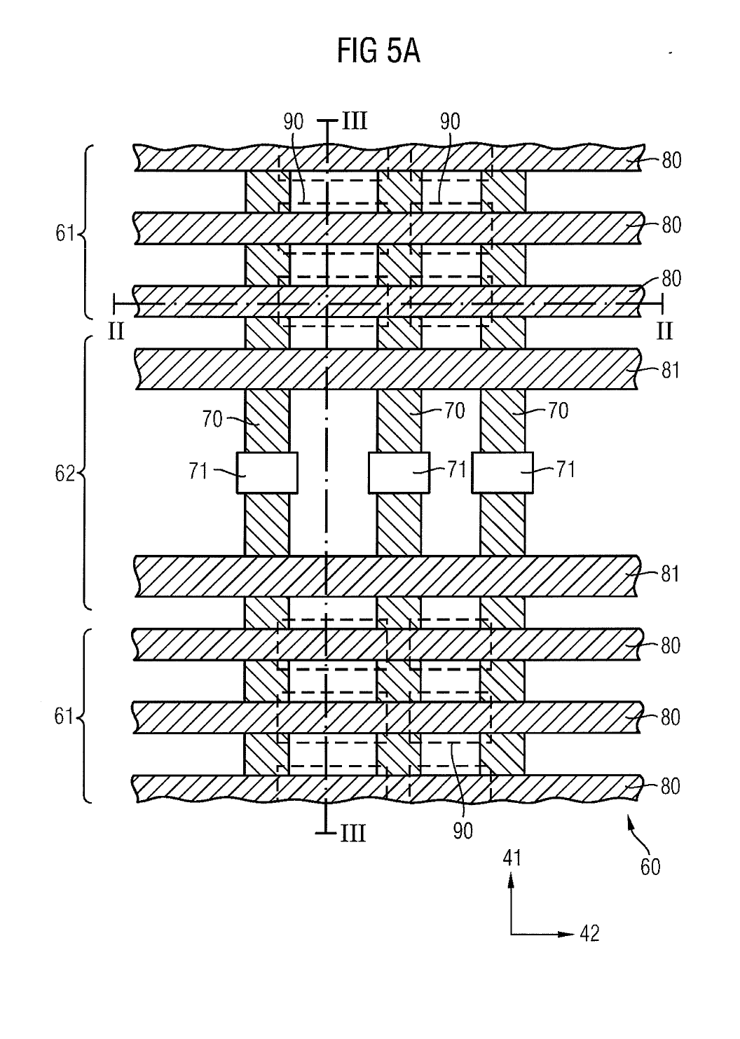

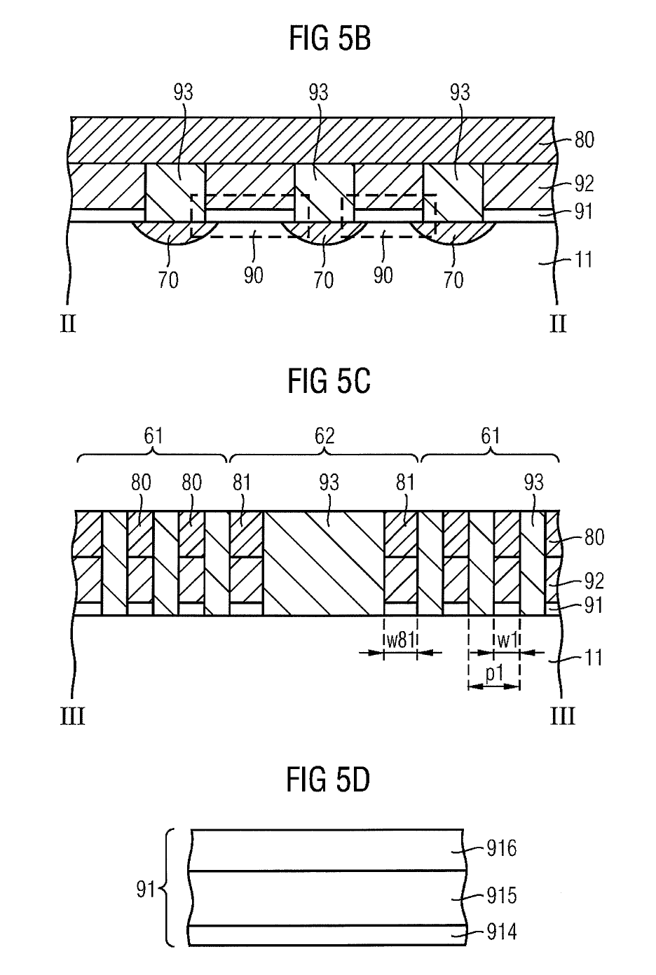

By way of example, the memory device may be a semiconductor memory device, and the memory cells may be formed at least partially within a semiconductor substrate. FIGS. 4A to 5D illustrate embodiments of the described memory device.

FIGS. 4A to 4C illustrate a NAND-device with non-volatile, for instance floating gate, memory cells. FIG. 4A shows a plan view on such a memory device 60. Active areas 94 run along a first direction 41, whereas second conductive lines 80 run along a second direction 42. First conductive lines are arranged above second conductive lines 80 and are not shown in FIG. 4A for the sake of simplicity. However, contacts 71 of first conductive lines to active areas 94 are shown. Memory cells 90 are arranged beneath the crosspoints of second conductive lines 80 with active areas 94. Memory cells 90 are shown in FIG. 4A only for one active area 94, for simplification, but are arranged at other active areas 94 as well. Second conductive lines 80, which may be wordlines, are arranged in subsets within a first section 61 of memory device 60. In a second section 62 of memory device 60, additional conductive lines 81, known as select gate lines, are arranged at the edges of first sections 61. In the space between additional lines 81, contacts 71 are arranged. In other portions of memory device 60, source contacts to active areas 94 are arranged in section 62.

FIG. 4B shows a cross sectional view through memory device 60 along line I-I, shown in FIG. 4A, that is along an active area 94. As can be seen, active areas 94 are formed within a substrate 11, being a semiconductor substrate. Within active areas 94 source/drain regions of memory cells 90 are formed. Each memory cell 90 comprises a source and a drain region, a component for storing information 91 and a control gate, which may form a part of second conductive line 80. The source region of one memory cell 90 is connected to the drain region of a neighboring memory cell 90. Thereby the memory cells are connected in series. Conductive lines 80 have a width w1 and a pitch p1 as described with respect to FIG. 2H. Additional conductive lines 81 have a width w81 greater than w1. In the space between two neighboring lines 81, contact 71 of a first conductive line 70 to active area 94 is arranged. Additional lines 81 and contact 71 are arranged in second section 62, whereas lines 80 are arranged in first section 61 of memory device 60. An insulating material 93 insulates single memory cells 90 and single second lines 80 from each other and insulates first lines 70 and second lines 80 from each other. First conductive lines 70 may be bitlines.

FIG. 4C shows a detail of one memory cell 90, in particular the component for storing information 91 in more detail. The component for storing information 91 comprises: a tunneloxide 911, a floating gate 912 and an insulating layer 913. Tunneloxide 911 is adjacent to substrate 11 and insulating layer 913 is adjacent to the control gate. Information is stored by a charge within floating gate 912, wherein the charge is brought in and removed from floating gate 912 by tunneling through tunneloxide 911.

FIGS. 5A to 5D illustrate a memory device with NROM memory cells. FIG. 5A shows a plan view on such a memory device 60. First conductive lines 70 run along a first direction 41, whereas second conductive lines 80 run along a second direction 42. Memory cells 90 are arranged beneath second conductive lines 80 in between two neighboring first conductive lines 70. Second conductive lines 80, which are wordlines, are arranged in subsets within a first section 61 of memory device 60. In a second section 62 of memory device 60, additional conductive lines 81 are arranged at the edges of first sections 61. Contacts 71 of first conductive lines 70 to a higher wiring or metallization level are arranged in the space between additional lines 81.

FIG. 5B shows a cross sectional view through memory device 60 along line II-II, shown in FIG. 5A, that is along a second conductive line 80. As can be seen, first conductive lines 70 are formed within a substrate 11, being a semiconductor substrate. They form source/drain regions of memory cells 90. Each memory cell 90 comprises a source and a drain region, a component for storing information 91 and a gate electrode 92 connected to a second conductive line 80. An insulating material 93 insulates single memory cells from each other and insulates first lines 70 and second lines 80 from each other.

FIG. 5C shows a cross sectional view through memory device 60 along line III-III, shown in FIG. 5A, that is along first direction in between two first conductive lines 70. As can be seen, second conductive lines 80 have a width w1 and a pitch p1 as described with respect to FIG. 2H. Additional conductive lines 81 have a width w81 greater than w1. In the space between two neighboring lines 81, insulating material 93 is arranged. Additional lines 81 are arranged in second section 62, whereas lines 80 are arranged in first section 61 of memory device 60.

FIG. 5D shows a detail of one memory cell 90, in particular a component for storing information 91 in more detail. The component for storing information 91 comprises a lower boundary layer 914, a charge storage layer 915 and an upper boundary layer 916. Lower boundary layer 914 is adjacent to substrate 11 and upper boundary layer 916 is adjacent to gate electrode 92. Information is stored by a charge within the charge storage layer 915, wherein the charge is brought in and removed from the charge storage layer 915 by tunneling through the lower boundary layer 914. The stored charge determines the threshold voltage of the transistor and can be detected by applying corresponding voltages to the source and drain regions and to gate electrode 92, respectively.

Although a floating gate device and a NROM device are shown by way of example for a memory device, the described method may be used for manufacturing any other memory devices, and the described device may be any other memory device. For instance, nonvolatile memory devices such as charge trapping devices, (e.g., SONOS, TANOS or SANOS devices), in different architectures, (e.g., NAND or NOR architecture), lie in the scope of the described memory device. Furthermore, DRAM devices, MRAM devices, FRAM devices or Phase Changing Memory (PCM) devices lie in the scope of the described memory device, and the methods of manufacturing such memory devices lie in the scope of the described method.

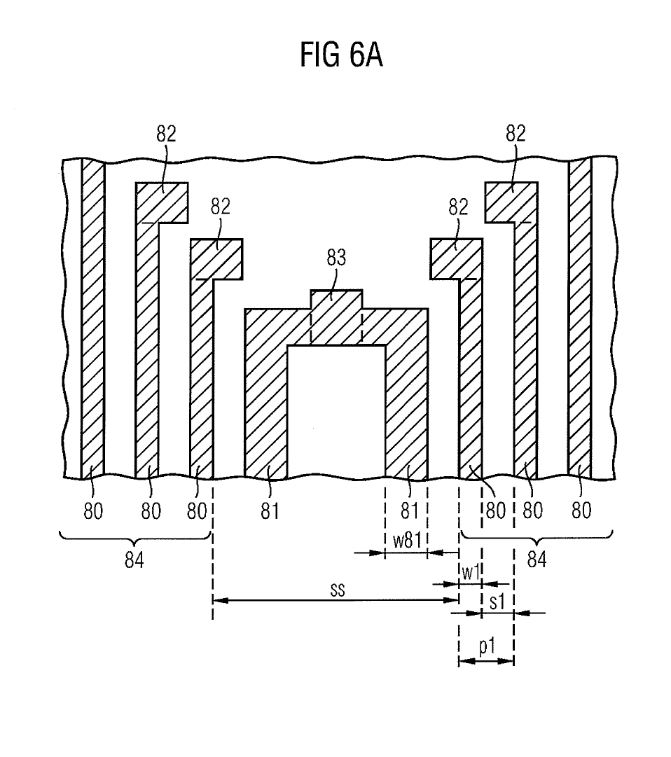

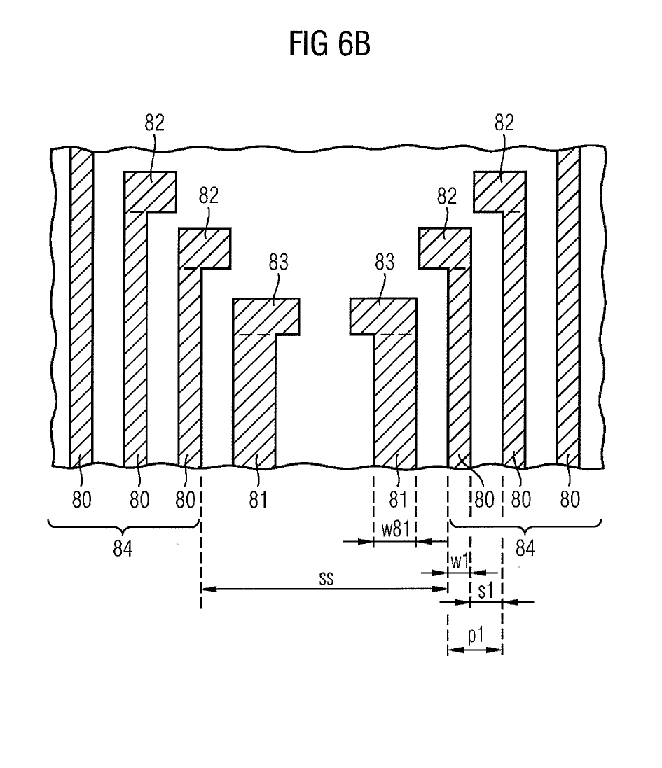

FIG. 6A shows a plan view on an embodiment of the described device. As can be seen, a fan-out region of conductive lines 80 of a device is shown. Conductive lines 80 are arranged in subsets 84 and have a width w1 and a pitch p1, wherein p1=w1+s1. S1 is the space between two neighboring conductive lines 80. A landing pad 82 is arranged at the end of each conductive line 80. Two neighboring subsets 84 are arranged at a distance ss from each other. In that distance ss two additional conductive lines 81 are arranged. These additional lines 81 may be dummy conductive lines of a memory device, as for instance described with respect to FIGS. 5A to 5D. Conductive lines 80 are then second conductive lines connected to memory cells. Additional lines 81 are dummy conductive lines since they are not used to address a memory cell. However these dummy conductive lines 81 may be electrically connected with each other and held at a predetermined electrical potential by connecting them using an additional landing pad 83. This may be advantageous for operating the device, because a smaller potential drop between a conductive line 80 at an edge of a subset 84 and dummy line 81 occurs.

FIG. 6B shows a plan view on another embodiment of the described device. As can be seen, a fan-out region of conductive lines 80 of a device is shown. Conductive lines 80 are arranged in subsets 84 and have a width w1 and a pitch p1, wherein p1=w1+s1. S1 is the space between two neighboring conductive lines 80. A landing pad 82 is arranged at the end of each conductive line 80. Two neighboring subsets 84 are arranged at a distance ss from each other. In that distance ss two additional conductive lines 81 are arranged. These additional lines 81 may be select gate lines of a memory device, as for instance described with respect to FIGS. 4A to 4C. Conductive lines 80 are then second conductive lines connected to memory cells. An additional landing pad 83 is arranged at the end of each additional conductive line 81.

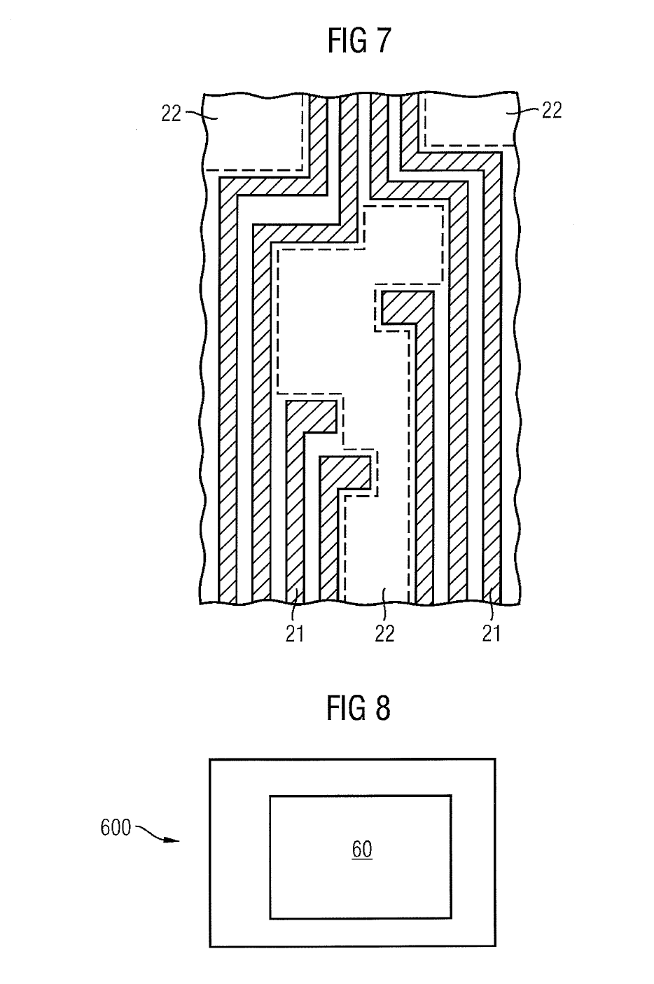

FIG. 7 shows a further embodiment of the described device manufactured by the described method. As can be seen, the device comprises structures 21 and sections 22 characterized by the dashed lines. Structures 21 may for instance be conductive lines in a metallic wiring level comprising contact structures and may be formed by a process comprising lithographic steps and a pitch fragmentation process. Structures 21 are arranged outside sections 22. Sections 22 have an irregular shape and may not comprise structures in the level of structures 21. Small and regular spaces between structures 21 may be formed in the same process as structures 21. Large and irregular shaped sections 22, however, are difficult to form in the same process as structures 21, at least if the lithographic process is a photolithographic process. The use of the described method is advantageous for forming such devices as shown for example in FIG. 7.

FIG. 8 shows a system 600 comprising a memory device 60. Memory device 60 may be formed as described with respect to FIGS. 4A to 5D. System 600 may be an entertainment system, (e.g., a MP3 player, a DVD recorder or a mobile phone). System 600 may be a data processing system, (e.g., a personal computer or a hand held computer). System 600 may be a system for storing data, (e.g., a storage card, a USB stick or a solid state hard disk).

The embodiments of the invention described in the foregoing are examples given by way of illustration and the invention is in no ways limited thereto. Any modification, variation and equivalent arrangement should be considered as being included within the scope of the invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adoption or variations of the specific embodiments discussed herein. Therefore it is intended that this invention be limited only by the claims and the equivalents thereof.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of manufacturing structures in a workpiece, the method comprising:
providing a portion of a cover layer on a predetermined section of the workpiece;
providing a resist layer over the workpiece and the cover layer and patterning resist structures in the resist layer; and
patterning the workpiece using the patterned resist layer and the cover layer as an etching mask.

2. The method of claim 1, further comprising:
carrying out a pitch fragmentation process subsequent to patterning the workpiece.

3. The method of claim 2, further comprising:
removing at least a part of the predetermined section of the workpiece subsequent to carrying out the pitch fragmentation process.

4. The method of claim 1, further comprising:
removing at least a part of the predetermined section of the workpiece subsequent to patterning the workpiece.

5. The method of claim 1, wherein the resist structures are line structures, and wherein the portion of the cover layer is arranged beneath a plurality of the line structures.

6. The method of claim 5, wherein the portion of the cover layer has a rectangular shape or a line shape.

7. The method of claim 1, wherein workpiece structures obtained by patterning the workpiece structures are conductive lines of a semiconductor device.

8. A method of manufacturing structures in a workpiece, the method comprising:
patterning resist structures in a resist layer disposed over the workpiece;
patterning the workpiece using the patterned resist layer as an etching mask, thereby obtaining workpiece structures;
removing the workpiece structures from a predetermined section of the workpiece; and
carrying out a pitch fragmentation process subsequent to removing the workpiece structures from the predetermined section.

9. The method of claim 8, further comprising:
removing at least a part of the predetermined section of the workpiece subsequent to carrying out the pitch fragmentation process.

10. The method of claim 8, wherein workpiece structures obtained by carrying out the pitch fragmentation process are conductive lines of a semiconductor device.

11. A method of forming a memory device, the method comprising:
forming first conductive lines;
providing memory cells;
providing a conductive layer for forming second conductive lines;
providing a portion of a cover layer over a predetermined section of the conductive layer;
providing a resist layer over the conductive layer and the cover layer and patterning resist structures in the resist layer; and
forming second conductive lines by patterning the conductive layer, wherein forming the second conductive lines comprises an etching step using the patterned resist layer and the cover layer as an etching mask,
wherein at least a part of each memory cell is connected with at least one of the first conductive lines and the second conductive lines.

12. The method of claim 11, further comprising:
providing a masking layer above the conductive layer prior to providing the resist layer; and
patterning the masking layer using the patterned resist layer as an etching mask;
wherein the patterned masking layer and the cover layer are used as an etching mask for forming second conductive lines.

13. The method of claim 12, further comprising:
carrying out a pitch fragmentation process subsequent to patterning the masking layer and prior to patterning the conductive layer.

14. The method of claim 13, further comprising:
removing at least a part of the masking layer disposed over the predetermined section of the conductive layer subsequent to carrying out the pitch fragmentation process and prior to patterning the conductive layer.

15. The method of claim 12, further comprising:
removing at least a part of the masking layer disposed over the predetermined section of the conductive layer subsequent to patterning the masking layer.

16. The method of claim 11, further comprising:
carrying out a pitch fragmentation process subsequent to patterning the conductive layer.

17. The method of claim 16, further comprising:
removing at least a part of the predetermined section of the conductive layer subsequent to carrying out the pitch fragmentation process.

18. The method of claim 11, further comprising:
removing at least a part of the predetermined section of the conductive layer subsequent to forming the second conductive lines.

19. A method of forming a memory device comprising:
forming first conductive lines;
providing memory cells;
providing a conductive layer for forming second conductive lines;
providing a resist layer over the conductive layer and patterning resist structures in the resist layer; and
forming second conductive lines by patterning the conductive layer, wherein forming second conductive lines comprises:
etching using the patterned resist layer as an etching mask;
removing structures obtained by the etching from a predetermined section of the conductive layer; and
carrying out a pitch fragmentation process subsequent to removing the structures;
wherein at least a part of each memory cell is connected with at least one of the first conductive lines and the second conductive lines.

20. The method of claim 19, further comprising:
providing a masking layer above the conductive layer prior to providing the resist layer; and
patterning the masking layer, wherein patterning the masking layer comprises an etching step using the patterned resist layer as an etching mask;
wherein the patterned masking layer is used as an etching mask for forming second conductive lines.

21. The method of claim 20, further comprising:
removing at least a part of the masking layer disposed over the predetermined section of the conductive layer subsequent to patterning the masking layer.

22. The method of claim 19, further comprising:
removing at least a part of the predetermined section of the conductive layer subsequent to forming the second conductive lines.

23. A device comprising:
a plurality of first structures having a pitch and a dimension extending along a direction, wherein the pitch is smaller than 100 nm and the dimension is smaller than 50 nm; and
a structure section arranged between different subsets of the first structures, wherein a width of the structure section is greater than the pitch of the first structures.

24. The device of claim 23,
wherein the first structures are conductive lines extending along a first direction, the dimension is a width of the conductive lines, the conductive lines being arranged in subsets; and
wherein the structure section comprises a plurality of additional conductive lines extending along the first direction, each additional conductive line being arranged at an edge of a respective subset and having a width, the width of the additional conductive lines being greater than the width of the conductive lines.

25. The device of claim 24,
wherein the additional conductive lines are arranged at the edges of two adjacent subsets, the additional conductive lines being arranged next to each other and electrically connected.

26. The device of claim 25,
wherein each electrically connected additional conductive line is held at a predetermined electrical potential.

27. A memory device comprising:
first conductive lines extending along a first direction;
second conductive lines extending along a second direction different from the first direction, the second conductive lines being arranged in subsets and having a width smaller than 50 nm and a pitch smaller than 100 nm;
additional conductive lines extending along the second direction, each of the additional conductive lines being arranged at an edge of a respective subset and having a width greater than the width of the second conductive lines; and
a plurality of memory cells.

28. The memory device of claim 27, wherein the additional conductive lines are not used to address a memory cell.

29. The memory device of claim 27, wherein the additional conductive lines of two adjacent subsets are arranged next to each other and are electrically connected.

30. The memory device of claim 29,
wherein each electrically connected additional conductive line is held at a predetermined electrical potential.

31. An entertainment system comprising the memory device of claim 27.

32. A data processing system comprising the memory device of claim 27.

33. A system for storing data comprising the memory device of claim 27.

34. The system of claim 33, wherein the system is a storage card.

35. The system of claim 33, wherein the system is a USB stick.

36. The system of claim 33, wherein the system is a solid state hard disk.

37. A memory device comprising:
first conductive lines extending along a first direction;
second conductive lines extending along a second direction different from the first direction, the second conductive lines being arranged in subsets and having a width smaller than 50 nm and a pitch smaller than 100 nm;
a plurality of memory cells arranged in a NAND architecture; and
select gate lines extending along the second direction, each of the select gate lines being arranged at an edge of a respective subset and having a width greater than the width of the second conductive lines and a distance to an adjacent second conductive line, wherein the distance is equal to the difference of the pitch and the width of the second conductive.

38. The memory device of claim 37,
wherein the first conductive lines are bitlines and the second conductive lines are wordlines.
